(19) United States
(12) Patent Application Publication
(10) Pub. No.: US 2003/0013211 A1
(43) Pub. Date: Jan. 16, 2003

(54) Mend method for breakage dielectric film

(76) Inventors: Chu-Chun Hu, Hsinchu (TW); Hsiao-Che Wu, Chung-Li City (TW)

Correspondence Address: OPPENHEIMER WOLFF & DONNELLY, P. O. BOX 10356, PALO ALTO, CA, 94303, US

(21) Appl. No.: 09/905,498

(22) Filed: Jul. 13, 2001

(51) Int. Cl. H01L 21/00; H01L 21/31; H01L 21/469

(52) U.S. Cl. 438/4; 438/760; 438/761

(57) ABSTRACT

The present invention offers a mend method for breakage dielectric film, applied to the reworking of a substrate with a conductive layer and a first dielectric layer in which an in-film particle has been embedded. In the subsequent planarization, the particle causes the formation of a hole defect. The method features the steps of: forming a second dielectric layer on the first dielectric layer to cover the hole defect; forming an SOG layer on the second dielectric layer to repair the hole defect; partially etching back to level the SOG layer; and forming a third dielectric layer on the SOG layer. The present invention thus reworks the damaged dielectric layer by the SOG process.

### BACKGROUND OF THE INVENTION

1. Field of the Invention

The present invention relates to the semiconductor manufacturing process, and more particularly, to a method of reworking a dielectric layer with a hole defect.

2. Description of the Related Art

In semiconductor manufacture, to accommodate an increase in integration, the interconnect process commonly uses intermetal dielectric (IMD) layers to isolate conducting structures, such as metal layers, from subsequently deposited conducting layers. Intermetal dielectric layers are also useful in performing planarization.

However, circuit short problems frequently occur in the intermetal dielectric layers. Refer to FIG. 1a, there is an in-film particle 11 included in an intermetal dielectric layer 15 on a substrate 10. Then refer to FIG. 1b, in the subsequent chemical polishing (CMP), because the particle 11 is dropped during polishing, a hole defect 12 is formed on the surface of the dielectric layer 15. If the hole defect 12 is deep enough, as shown in FIG. 1c, first metal layers 13 will be exposed. So, when forming a second metal layer 14, the cross fail phenomenon occurs between the first metal layers 13 and the second metal layer 14.

At present, the common industry solution is to form a thin oxide layer on the dielectric layer 15, then form the second metal layer 14. The thin oxide layer is also depicted as a cap oxide layer.

Although the cap oxide layer can isolate the different metal layers 13,14, the previously described method still has some disadvantages, as follows:

(1) Capping the thin oxide layer or the cap oxide layer on the hole causes a drop in elevation, creating photo defocus and inaccuracy in the subsequent dielectric or metal layer lithography process.

(2) Inconsistent flatness affects subsequent metal layer depositing and planarization.

(3) When performing a defect scan, for example, a KLA scan after the etching process of the second metal layer 14, the image of the first metal layer 13 is also caught, so the problem of the drop in elevation is not solved yet.

### SUMMARY OF THE INVENTION

An object of the present invention is to provide a method of reworking a dielectric layer. It especially relates to the reworking of a substrate with a conductive layer and an intermetal dielectric layer in which an in-film particle has been embedded. In the subsequent chemical polishing (CMP), the particle causes the formation of a hole defect on the surface of the dielectric layer. The present invention repairs the hole defect in the dielectric layer by isolating the different metal layers, thus preventing circuit shorting, and keeping the repaired dielectric layer smooth.

In accordance with the object of the invention, a method is provided, especially applied to the reworking of a substrate with a conductive layer and a first dielectric layer in which an in-film particle causing the formation of a hole defect in the subsequent planarization. A second dielectric layer is formed on the first dielectric layer to cover the surface of the hole defect. Forming an SOG layer on the second dielectric layer repairs the hole defect. Partial etching back levels the SOG layer, and forms a third dielectric layer on the SOG layer.

In accordance with the object of the invention, another method is provided, especially applied to the reworking of a substrate with a conductive layer and a first dielectric layer in which an in-film particle causing the formation of a hole defect in the subsequent planarization. A second dielectric layer is formed on the first dielectric layer to cover the surface of the hole defect. Forming an SOG layer on the second dielectric layer repairs the hole defect, and forms a third dielectric layer on the SOG layer.

Consequently, the methods of the present invention have the following advantages:

(1) The present methods can isolate different metal layers precisely, preventing circuit shorting.

(2) In subsequent dielectric or metal layer lithography process, because the surface of the cap oxide layer of the traditional method is repaired and leveled by the SOG layer of the present methods, the drop in elevation of the traditional method is solved, improving photo focus accuracy.

(3) Improved flatness creates better photo focus and enhances effectiveness in subsequent metal layer or dielectric layer deposition and planarization.

(4) During defect scanning, for example, an KLA scan after etching the upper metal layer, the image of the bottom metal layer is not caught, so elevation drop problems are solved.

### BRIEF DESCRIPTION OF THE DRAWINGS

The present invention can be more fully understood by reading the subsequent detailed description in conjunction with the examples and references made of the accompanying drawings, wherein:

FIGS. 1a-1c are schematic views of a dielectric layer in which an in-film particle has been embedded. Because the particle is dropped during planarization, a hole defect is formed on the surface of the dielectric layer;

FIGS. 2a-2f are sectional diagrams of the first embodiment of the present invention;

FIGS. 3a-3e are sectional diagrams of the second embodiment of the present invention;

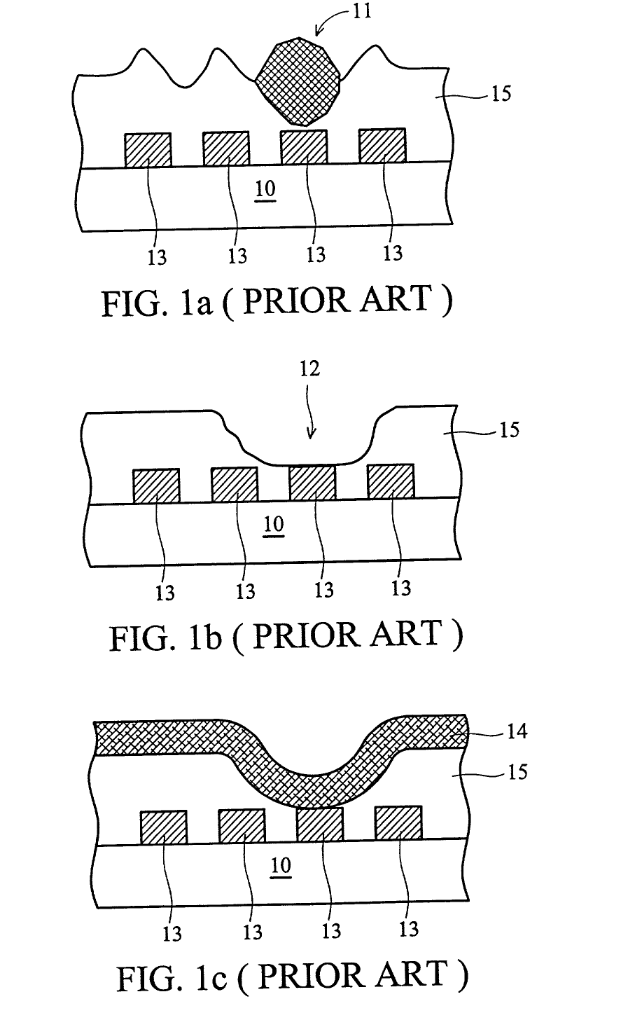

### DETAILED DESCRIPTION OF THE PREFERRED EMBODIMENT

### The First Embodiment

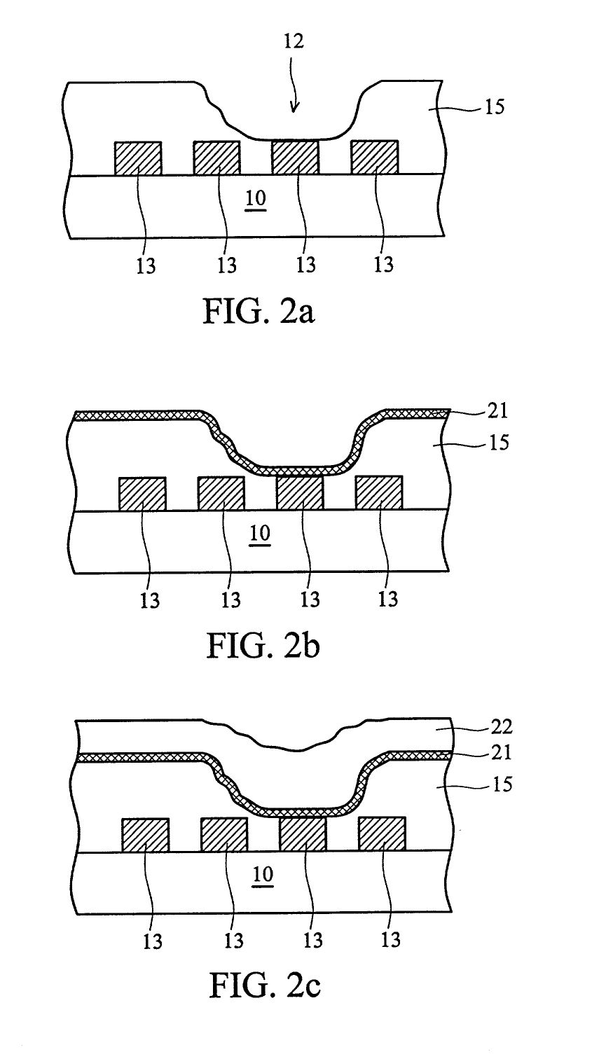

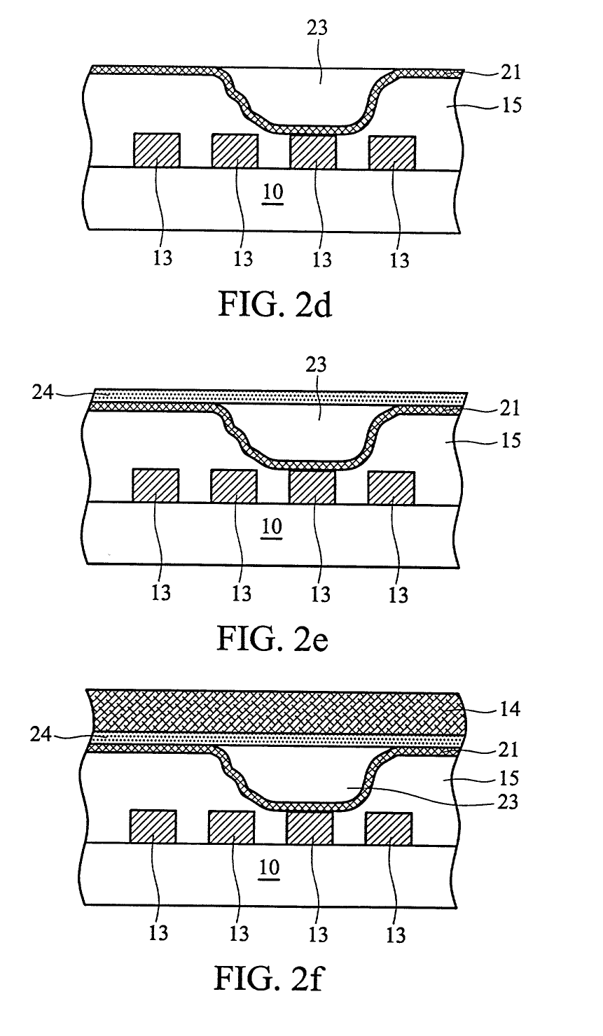

Refer to FIGS. 2a-2f. In the first embodiment, the present invention offers a method of reworking a dielectric layer with a hole defect. It especially relates to the reworking of a substrate with a conductive layer and an intermetal dielectric layer in which an in-film particle has been embedded. In the subsequent planarization, the particle causes the formation of a hole defect on the surface of the dielectric layer.

Refer to FIG. 2a. Beginning with a semiconductor substrate 10 with a plurality of first conductive layers 13 and a first dielectric layer 15. A hole defect 12 of the first dielectric layer 15 is formed while performing planarization by, for example, CMP polishing for the first dielectric layer 15. The first conductive layers 13 are metal, such as Cu, Al, or Al alloy, and the first dielectric layer 15 may be, for example, silicon oxide deposited by CVD.

Next, refer to FIG. 2b, a conformal second dielectric layer 21 is formed on the first dielectric layer 15 to cover the surface of the hole defect 12. The second dielectric layer 21 may be, for example, a thin silicon oxide layer deposited by PECVD.

Next, refer to FIG. 2c, an SOG layer 22 is formed on the second dielectric layer 21 to repair the hole defect 12, and then the SOG layer 22 is cured.

Next, refer to FIG. 2d, partial etching back is performed on the SOG layer 22 until the surface of the second dielectric layer 21 is exposed, to form the smooth SOG layer 23. That is, the second dielectric layer 21 is used as an etching stop layer when partially etching back the SOG layer 22 by plasma.

Next, refer to FIG. 2e, where a third dielectric layer 24 is formed on the SOG layer 23 and the second dielectric layer 21. The third dielectric layer 24 may be, for example, a thin silicon oxide layer deposited by PECVD. The hole defect 12 of the dielectric layer 15 is thus mended.

Then, refer to FIG. 2f, where, after the step of forming a third dielectric layer 24 on the SOG layer 23 and the second dielectric layer 21, a conductive layer 14 is further formed on the third dielectric layer 21. The conductive layer 14 may be, for example, a Cu, Al, or Al alloy layer deposited by sputtering.

The Second Embodiment

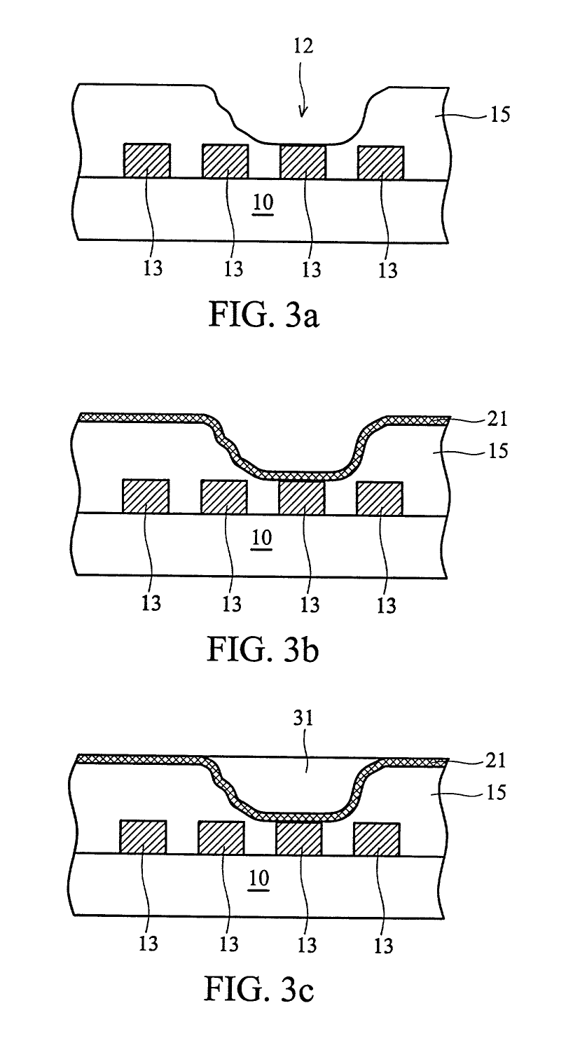

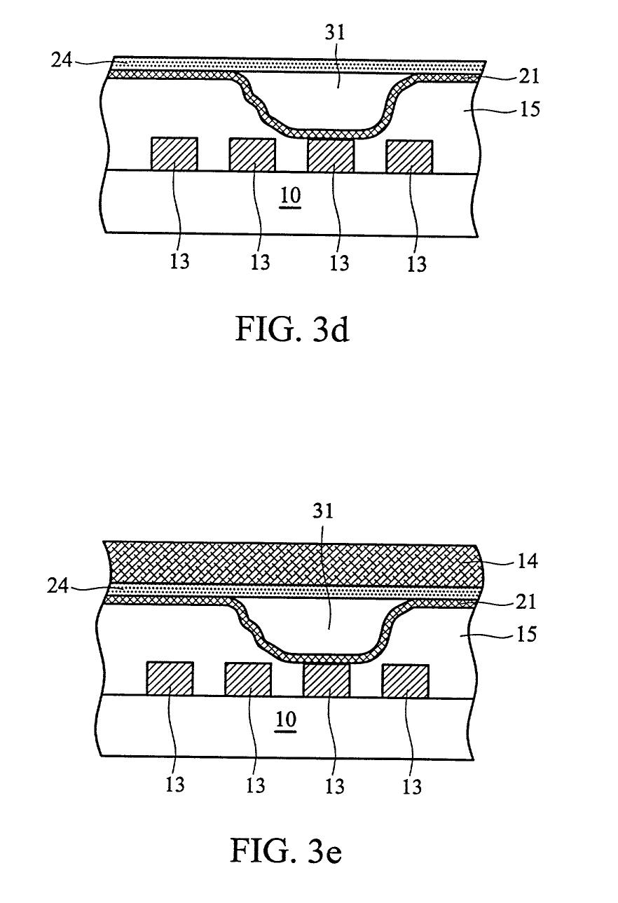

Refer to FIGS. 3a-3e. In this embodiment, the present invention offers another method of reworking a dielectric layer with a hole defect. It especially relates to the reworking of a substrate with a conductive layer and an intermetal dielectric layer in which an in-film particle has been embedded. In the subsequent planarization, the particle causes the formation of a hole defect on the surface of the dielectric layer.

Refer to FIG. 3a. On a semiconductor substrate 10 with a plurality of first conductive layers 13 and a first dielectric layer 15, a hole defect 12 of the first dielectric layer 15 is formed while performing planarization by, for example, CMP on the first dielectric layer 15. The first conductive layers 13 are metal, such as Cu, Al, or Al alloy, and the first dielectric layer 15 may be, for example, silicon oxide deposited by CVD.

Next, refer to FIG. 3b, where a conformal second dielectric layer 21 is formed on the first dielectric layer 15 to cover the surface of the hole defect 12. The second dielectric layer 21 may be, for example, a thin silicon oxide layer deposited by PECVD.

Refer now to FIG. 3c, where an SOG layer 31 is formed on the second dielectric layer 21 to repair the hole defect 12, and the SOG layer 31 is cured.

Next, referring to FIG. 3d, a third dielectric layer 24 is formed on the SOG layer 31 and the second dielectric layer 21. The third dielectric layer 24 may be, for example, a thin silicon oxide layer deposited by PECVD. The hole 12 of the dielectric layer 15 is thus mended.

Then, refer to FIG. 3e, after the step of forming a third dielectric layer 24 on the SOG layer 31 and the second dielectric layer 21, a conductive layer 14 is further formed on the third dielectric layer 21. The conductive layer 14 may be, for example, a Cu, Al, or Al alloy layer deposited by sputtering.

The present invention reworks the dielectric layer with a hole defect by isolating the different metal layers, thus preventing circuit shorting, and ensuring that the dielectric layers maintain the requisite smoothness for effective planarization.

The above embodiments also prevent cross fail between metal layers 13, 14, and achieve superior flatness before the sputtering of the upper metal layer 14. Additionally, defect image cannot be caught after defect scanning, for example, KLA defect scanning.

Finally, while the invention has been described by way of example and in terms of the above two preferred embodiments, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method of reworking a first dielectric layer with an embedded particle-caused hole defect after planarization process comprises the steps of:
forming a conformal second dielectric layer on the first dielectric layer to cover the surface of the hole defect;
forming an SOG layer on the second dielectric layer to repair the hole defect;
Partially etching back the SOG layer, during which the second dielectric layer is used as an etching stop layer; and
forming a third dielectric layer on the SOG layer.

2. The method according to claim 1, wherein the etching back is performed by plasma.

3. The method according to claim 1, wherein after the step of forming the SOG layer on the second dielectric layer, the SOG layer is cured.

4. The method according to claim 1, wherein after the step of forming the third dielectric layer on the SOG layer, a second conductive layer is formed on the third dielectric layer.

5. The method according to claim 1, wherein the first conductive layer comprises a metal layer formed by deposition.

6. The method according to claim 4, wherein the second conductive layer comprises a metal layer formed by deposition.

7. The method according to claim 1, wherein the first, second or third dielectric layer comprises a silicon oxide layer formed by deposition.

8. A method of reworking a first dielectric layer with an embedded particle-caused hole defect after planarization process comprises the steps of:
forming a conformal second dielectric layer on the first dielectric layer to cover the surface of the hole defect;
forming an SOG layer on the second dielectric layer to repair the hole defect; and
forming a third dielectric layer on the SOG layer.

9. The method according to claim 8, wherein the planarization is performed by CMP.

10. The method according to claim 8, wherein after the step of forming the SOG layer on the second dielectric layer, the SOG layer is cured.

11. The method according to claim 8, wherein after the step of forming the third dielectric layer on the SOG layer, further forming a second conductive layer on the third dielectric layer.

12. The method according to claim 8, wherein the first conductive layer comprises a metal layer formed by deposition.

13. The method according to claim 11, wherein the second conductive layer comprises a metal layer formed by deposition.

14. The method according to claim 1, wherein the first, second or third dielectric layer comprises a silicon oxide layer formed by deposition.
